(19) United States
(12) Patent Application Publication
(10) Pub. No.: US 2016/0037624 A1
(43) Pub. Date: Feb. 4, 2016

(54) FLEXIBLE PRINTED CIRCUIT BOARD AND MANUFACTURING METHOD THEREOF

(71) Applicant: SAMSUNG ELECTRO-MECHANICS CO., LTD., Suwon (KR)

(72) Inventors: Kyung-Chul Yu, Busan (KR); Ha-Il Kim, Seoul (KR); Young-Man Kim, Busan (KR); Dong-Gi An, Gimhae (KR)

(73) Assignee: SAMSUNG ELECTRO-MECHANICS CO., LTD., Suwon (KR)

(21) Appl. No.: 14/674,658

(22) Filed: Mar. 31, 2015

(30) Foreign Application Priority Data
Jul. 29, 2014 (KR) 10-2014-0096725

(51) Int. Cl. H05K 1/02; H05K 1/11; H05K 1/09; H05K 3/46; H05K 3/02

(52) U.S. Cl. CPC H05K 1/028; H05K 3/4641; H05K 3/02; H05K 3/4652; H05K 1/0298; H05K 1/09; H05K 1/111; H05K 2203/0548; H05K 2203/061; H05K 2203/107; H05K 2201/0355; H05K 2201/09036

(57) ABSTRACT

A flexible printed circuit board and a manufacturing method thereof are disclosed. The flexible printed circuit board in accordance with an aspect of the present invention includes: a base board including a flexible region; an inner circuit layer formed on the base board; a flexible laminate laminated on the base board and having a portion thereof removed, the portion having been laminated on the flexible region; and an outer circuit layer formed on the flexible laminate. The flexible laminate is formed by having an adhesive layer, a polyimide layer and a copper foil layer sequentially laminated and is arranged and laminated in such a way that the adhesive layer faces the base board.

### CROSS-REFERENCE TO RELATED APPLICATIONS

This application claims the benefit of Korean Patent Application No. 10-2014-0096725, filed with the Korean Intellectual Property Office on Jul. 29, 2014, the disclosure of which is incorporated herein by reference in its entirety.

### BACKGROUND

1. Technical Field

The present invention relates to a flexible printed circuit board and a manufacturing method thereof.

2. Background Art

Many of today's electronic products increasingly need to be smaller and thinner and to be designed to have a specific external appearance. To realize electronic products meeting these requirements, printed circuit boards (PCBs) that are inserted in the electronic products have become more important.

The printed circuit boards may be classified into, according to the number of layers, single side PCBs, in which wiring is formed on one side of an insulation layer only, double side PCBs, in which wiring is formed on both sides of an insulation layer, and multi-layered PCBs, in which wiring is formed on multiple layers.

Moreover, the PCBs may be classified into, according to a material used therein, rigid PCBs, which use a rigid material, flexible PCBs, which use a flexible material, and rigid flexible PCBs, which use a combination of a rigid material and a flexible material.

Among these different types of PCBs, the flexible PCBs are increasingly used as the boards that are inserted in the electronic products in order to cope with the increasing demand for smaller and thinner electronic products. Moreover, in addition to smartphones and tablet PCs having various functions, an increasing number of watch-type, bracelet-type and necklace-type wearable products have been developed, requiring various structures and designs of circuit boards that are capable of realizing these wearable products.

The related art of the present invention is disclosed in Korea Patent Publication No. 10-2013-0097473 (laid open on Sep. 3, 2013).

### SUMMARY

An embodiment of the present invention provides a flexible printed circuit board and a manufacturing method thereof in which a build-up layer is laminated on a base board by use of a flexible laminate that is formed by having an adhesive layer, a polyimide layer and a copper foil layer laminated sequentially.

Here, laser processing for a flexible region may be performed by using a portion of the copper foil layer as a laser mask, and a coverlay layer may be formed by removing the copper foil layer used as the laser mask.

### BRIEF DESCRIPTION OF DRAWINGS

FIG. 1 shows a flexible printed circuit board in accordance with an embodiment of the present invention.

FIG. 2 is a flow diagram showing a method of manufacturing a flexible printed circuit board in accordance with an embodiment of the present invention.

FIG. 3, FIG. 4, FIG. 5, FIG. 6, FIG. 7 and FIG. 8 show major processes of the method of manufacturing a flexible printed circuit board in accordance with an embodiment of the present invention.

### DETAILED DESCRIPTION

Hereinafter, a flexible printed circuit board and a manufacturing method thereof in accordance with the present invention will be described with reference to the accompanying drawings. In describing the present invention with reference to the accompanying drawings, any identical or corresponding elements will be assigned with same reference numerals, and their description will not be provided redundantly.

When one element is described to be “coupled” to another element, it does not refer to a physical, direct contact between these elements only, but it shall also include the possibility of yet another element being interposed between these elements and each of these elements being in contact with said yet another element.

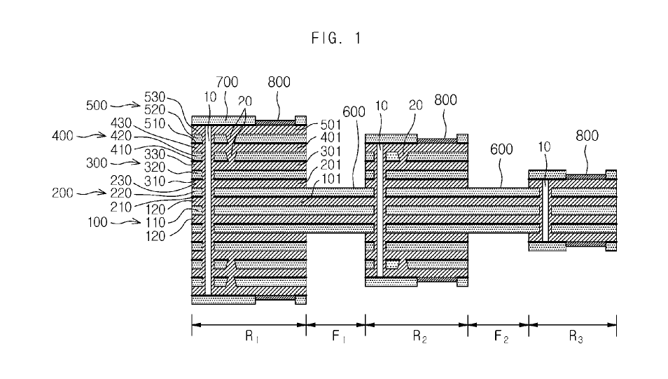

FIG. 1 shows a flexible printed circuit board in accordance with an embodiment of the present invention.

As shown in FIG. 1, a flexible printed circuit board 1000 in accordance with an embodiment of the present invention may include a base board 100, an inner circuit layer 101, flexible laminates 200, 300, 400, 500 and outer circuit layers 201, 301, 401, 501, and may further include a coverlay layer 600 and a pad layer 800.

The base board 100, which includes flexible regions F1, F2, may form a core in the flexible printed circuit board 1000 in accordance with the present embodiment. Here, the base board 100 may be a laminated plate, such as a flexible copper clad laminate (FCCL), in which a copper foil 120 is laminated on both sides of a polyimide-based flexible insulation layer 110.

The flexible regions F1, F2 are regions that are relatively more flexible in the flexible printed circuit board in accordance with the present embodiment and may be deformed relatively flexibly by warpage. Rigid regions R1, R2, R3, which are remaining regions excluding the flexible regions F1, F2, form a build-up layer by having one or more of the flexible laminates 200, 300, 400, 500 laminated on the base board 100 and may be deformed relatively limitedly by warpage.

The inner circuit layer 101 is a circuit pattern layer formed on the base board 100. A specific circuit pattern layer may be formed by processing, for example, exposing and etching, the copper foil 120 laminated on both sides of the flexible insulation layer 110.

For instance, the inner circuit layer 101 may be formed by a subtractive process, an additive process or a modified semi additive process, depending on the manufacturing process.

When forming the inner circuit layer 101, an interconnection may be made by forming a through-hole 10 having an inner wall thereof plated in the inner circuit layer 101 for electrical connection between the both sides of the flexible insulation layer 110.

The flexible laminates 200, 300, 400, 500, which are laminated on the base board 100, are configured by removing portions thereof that are laminated in the flexible regions F1, F2, hence being laminated in the rigid regions R1, R2, R3 of the flexible printed circuit board 1000 in accordance with the present embodiment to form the build-up layer.

Although it is illustrated in FIG. 1 as an example of the flexible printed circuit board 1000 that there are four flexible laminates 200, 300, 400, 500 laminated on each of two surfaces of the base board 100, it shall be appreciated that the present invention is not restricted to what is illustrated herein and that the number of flexible laminates 200, 300, 400, 500 laminated on each of the two surfaces of the base board 100 may vary as necessary.

In such a case, the flexible laminates 200, 300, 400, 500 are formed by having adhesive layers 210, 310, 410, 510, polyimide layers 220, 320, 420, 520 and copper foil layers 230, 330, 430, 530 sequentially laminated, respectively, and are arranged and laminated in such a way that the adhesive layers 210, 310, 410, 510 face the base board 100.

For example, one flexible laminate 200 is configured by having the adhesive layer 210, the polyimide layer 220 and the copper foil layer 230 laminated sequentially, and this flexible laminate 200 is laminated on the base board 100 in such a way that the adhesive layer 210 of this flexible laminate 200 is in contact with the base board 100.

Moreover, in case multiple layers of the flexible laminates 200, 300, 400, 500 are laminated, lamination may be repeated in such a way that, for example, the adhesive layer 310 of the flexible laminate 300, which is to be newly laminated, is in contact with the copper foil layer 230 of the flexible laminate 200, which is already laminated.

The outer circuit layers 201, 301, 401, 501, which are circuit pattern layers formed on the flexible laminates 200, 300, 400, 500, may be formed by use of an etching process using photolithography or an additive process (plating process).

Moreover, the outer circuit layers 201, 301, 401, 501 may be connected with the inner circuit layer 101 through a via 20 or the through-hole 10 penetrating the flexible laminates 200, 300, 400, 500, but it shall be appreciated that the present invention is not restricted to what is illustrated herein and may be varied as necessary.

As described above, the flexible printed circuit board 1000 in accordance with the present embodiment may have the build-up layer thereof formed by laminating the modularized flexible laminates 200, 300, 400, 500 on the base board 100 and thus may be manufactured in a simpler process than compressing the prepreg and the copper foil after coating a separate adhesive material.

Moreover, by using the modularized flexible laminates 200, 300, 400, 500, the build-up layer may have an improved inter-layer matching and may be relatively thinner.

In the flexible printed circuit board 1000 in accordance with the present invention, the flexible regions F1, F2 may be formed by removing portions of the flexible laminates 200, 300, 400, 500 laminated on the base board 100 by use of etching or laser processing. Here, the laser processing may be performed by using a portion of the copper foil layer 230 of the flexible laminates 200, 300, 400, 500 as a laser mask.

The laser mask is a portion that performs a laser resist function during the laser processing and may protect a portion covered by the laser mask because the laser mask is not removed during the laser processing.

Meanwhile, as the copper foil layers 230, 330, 430, 530 are not removed although the adhesive layers 210, 310, 410, 510 and the polyimide layers 220, 320, 420, 520 are removed by the laser processing, the copper foil layers 230, 330, 430, 530 themselves may function as the laser mask.

Accordingly, since the flexible printed circuit board 1000 in accordance with the present embodiment does not need to form an additional laser resist layer but may use a portion of the copper foil layer 230 as the laser mask, the flexible printed circuit board 1000 in accordance with the present embodiment may be manufactured through a simpler process.

A specific exemplary embodiment of using a portion of the copper foil layer 230 as the laser mask will be described in greater detail when a method of manufacturing a flexible printed circuit board in accordance with an embodiment of the present invention is described.

The coverlay layer 600, which is laminated on the inner circuit layer 101 formed in the flexible regions F1, F2, may protect the inner circuit layer 101. Here, the coverlay layer 600 may be partially or entirely formed by removing the copper foil layer 230 that is used as the laser mask.

Generally, a coverlay is a composite film having a thermosetting flame-resistant epoxy adhesive coated on a polyimide film and may substantially have the same configuration as the flexible laminates 200, 300, 400, 500 with the copper foil layers 230, 330, 430, 530 removed.

Therefore, in the flexible printed circuit board 1000 in accordance with the present embodiment, it is not necessary to laminate an additional coverlay on the inner circuit layer 101, and the coverlay layer 600 may be formed with the polyimide layer 220 and the adhesive layer 210 that are exposed by removing the copper foil layer 230 used as the laser mask.

Meanwhile, as shown in FIG. 1, a separate coverlay layer 700 may be laminated in a certain rigid region R1 to protect the exposed outermost outer circuit layer 501.

The pad layer 800 is formed on the flexible laminates 300, 500 that are laminated in the regions R1, R2, R3 other than the flexible regions F1, F2, is electrically connected with the outer circuit layers 201, 401, and may have components such as electronic devices mounted thereon.

In such a case, the pad layer 800 may be partially or entirely formed by removing a portion of the copper foil layers 330, 530 arranged in outermost surfaces of the flexible laminates 200, 300, 400, 500 and removing portions of the polyimide layers 320, 520 and the adhesive layers 310, 510 by use of laser processing.

Specifically, a portion of the copper foil layers 330, 530 may be removed through, for example, etching, and when portions of the polyimide layers 320, 520 and the adhesive layers 310, 510 are removed by use of laser processing, the copper foil layers 230, 430 having been laminated therein may function as a laser mask.

Accordingly, portions of the polyimide layers 320, 520 and the adhesive layers 310, 510 may be removed, and the copper foil layers 230, 430 having been laminated therein may be subsequently exposed, for easier electrical connection with the pad layer 800.

Meanwhile, laser processing may be performed on the above-described separate coverlay layer 700 to expose the copper foil layer 530 having been laminated therein and then form the pad layer 800.

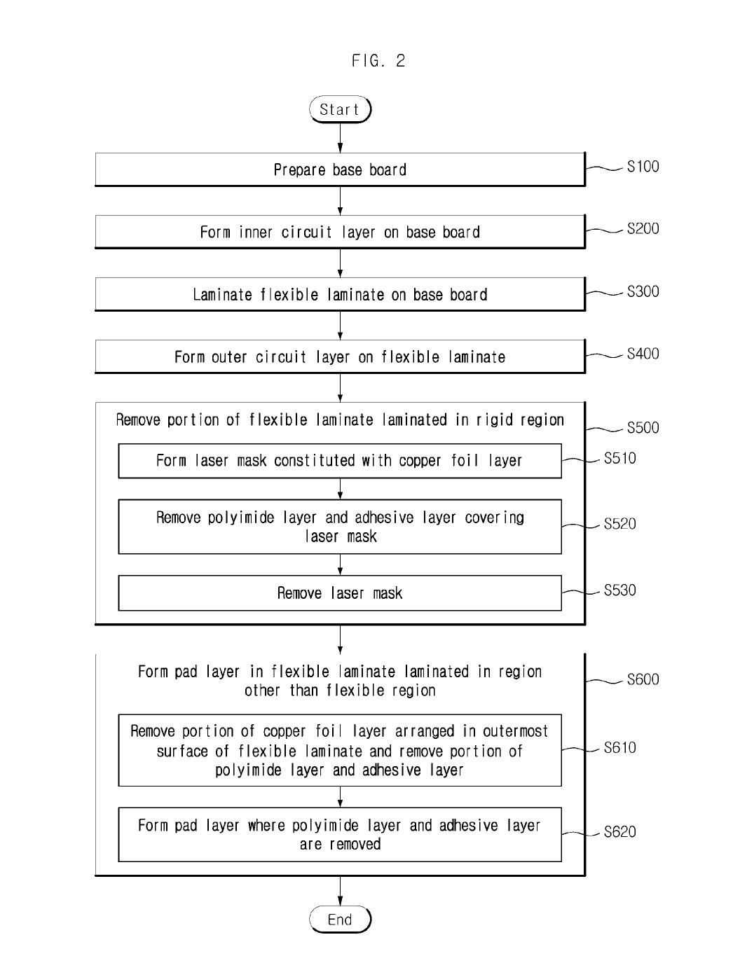

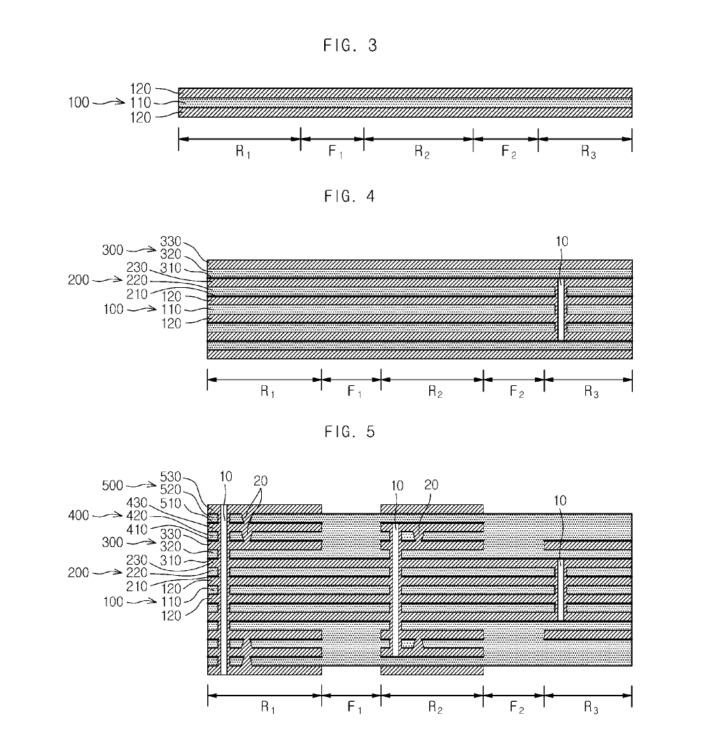

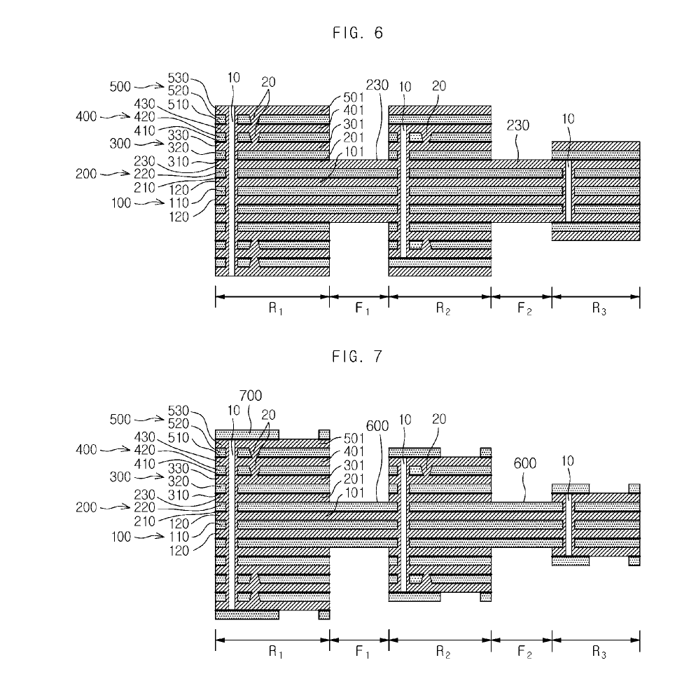

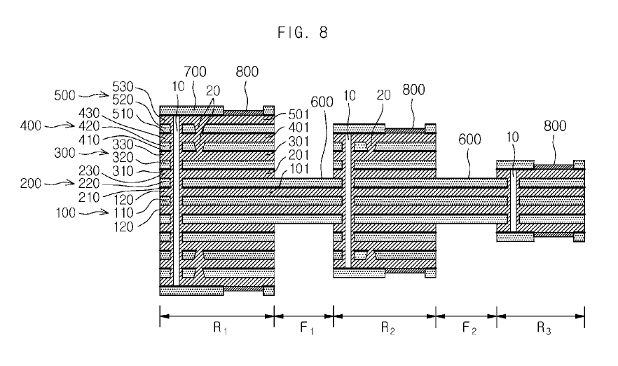

FIG. 2 is a flow diagram showing a method of manufacturing a flexible printed circuit board in accordance with an embodiment of the present invention. FIG. 3, FIG. 4, FIG. 5, FIG. 6, FIG. 7 and FIG. 8 show major processes of the method of manufacturing a flexible printed circuit board in accordance with an embodiment of the present invention.

Although it is illustrated in FIG. 3 to FIG. 8 as an example of the method of manufacturing a flexible printed circuit board that there are four flexible laminates 200, 300, 400, 500 laminated on each of two surfaces of a base board 100, it shall be appreciated that the present invention is not restricted to what is illustrated herein and that the number of flexible laminates 200, 300, 400, 500 laminated on each of the two surfaces of the base board 100 may vary as necessary.

As illustrated in FIG. 2 to FIG. 8, the method of manufacturing a flexible printed circuit board in accordance with an embodiment of the present invention starts with providing a base board 100 including flexible regions F1, F2 (S100, FIG. 3).

Here, the base board 100 may be a laminated plate, such as a flexible copper clad laminate (FCCL), in which a copper foil 120 is laminated on both sides of a polyimide-based flexible insulation layer 110.

Then, an inner circuit layer 101 is formed on the base board (S200). The inner circuit layer 101 is a circuit pattern layer formed on the base board 100, and a specific circuit pattern layer may be formed by processing, for example, exposing and etching, the copper foil 120 laminated on both sides of the flexible insulation layer 110.

When forming the inner circuit layer 101, an interconnection may be made by forming a through-hole 10 having an inner wall thereof plated in the inner circuit layer 101 for electrical connection between the both sides of the flexible insulation layer 110.

Next, flexible laminates 200, 300, 400, 500, which are formed by having adhesive layers 210, 310, 410, 510, polyimide layers 220, 320, 420, 520 and copper foil layers 230, 330, 430, 530 sequentially laminated, respectively, are arranged and laminated on the base board 100 in such a way that the adhesive layers 210, 310, 410, 510 face the base board 100 (S300, FIG. 4).

Here, FIG. 4 shows that two of the flexible laminates 200, 300 are laminated on each of the two surfaces of the base board 100 in the method of manufacturing a flexible printed circuit board in accordance with the present embodiment.

Specifically, one flexible laminate 200 is configured by having the adhesive layer 210, the polyimide layer 220 and the copper foil layer 230 sequentially laminated, and the flexible laminate 200 is laminated on the base board 100 in such a way that the adhesive layer 210 of this flexible laminate 200 is in contact with the base board 100. Then, lamination may be repeated in such a way that the adhesive layer 310 of the flexible laminate 300, which is to be newly laminated, is in contact with the copper foil layer 230 of the flexible laminate 200, which is already laminated.

Then, outer circuit layers 201, 301, 401, 501 are formed, respectively, on the flexible laminates 200, 300, 400, 500 (S400). Here, the outer circuit layers 201, 301, 401, 501 may be connected with the inner circuit layer 101 through a via 20 or the through-hole 10 penetrating the flexible laminates 200, 300, 400, 500.

Afterwards, portions of the flexible laminates 200, 300, 400, 500 that are laminated in the flexible regions F1, F2 are removed (S500, FIG. 5 to FIG. 7). That is, as the flexible laminates 200, 300, 400, 500 has a build-up layer formed in rigid regions R1, R2, R3 only and has the laminated portions removed in the flexible regions F1, F2, the flexible regions F1, F2 may be flexibly deformed relative to warpage.

As described above, the method of manufacturing a flexible printed circuit board in accordance with the present embodiment may have the build-up layer thereof formed by laminating the modularized flexible laminates 200, 300, 400, 500 on the base board 100 and thus may have a simpler process than compressing the prepreg and the copper foil after coating a separate adhesive material.

Moreover, by using the modularized flexible laminates 200, 300, 400, 500, the build-up layer may have an improved inter-layer matching and may be relatively thinner.

In the method of manufacturing a flexible printed circuit board in accordance with the present embodiment, the S500 step may include removing portions of the copper foil layers 330, 430, 530 in the flexible laminates 200, 300, 400, 500 and forming a laser mask constituted with the copper foil layer 230 that is not removed so as to cover the flexible regions F1, F2 of the base board 100 (S510, FIG. 5).

Here, if the copper foil layers 330, 430, 530 are exposed while the flexible laminates 200, 300, 400, 500 are sequentially laminated, the portions of the copper foil layers 330, 430, 530 may be removed through, for example, etching.

The S500 step may include, after the S510 step, removing the polyimide layers 320, 420, 520 and the adhesive layers 310, 410, 510 covering the laser mask (i.e., copper foil layer 230) through laser processing using the laser mask (i.e., copper foil layer 230) (S520, FIG. 6).

Accordingly, since the method of manufacturing a flexible printed circuit board in accordance with the present embodiment does not need to form an additional laser resist layer but may use a portion of the copper foil layer 230 as the laser mask, the method of manufacturing a flexible printed circuit board in accordance with the present embodiment may be much simpler.

Here, in the S520 step, the polyimide layers 420, 520 and the adhesive layers 410, 510 that are laminated in a certain rigid region R3 may be removed at the same time through laser processing.

Moreover, the S500 step may include, after the S520 step, removing the laser mask (i.e., copper foil layer 230) (S530, FIG. 7). That is, by removing the copper foil layer 230 that has been used as the laser mask may be removed to expose the polyimide layer 220 and the adhesive layer 210 laminated therein.

As such, since the exposed polyimide layer 220 and adhesive layer 210 form a coverlay layer 600, the inner circuit layer 101 may be protected even if no additional coverlay is laminated on the inner circuit layer 101.

In such a case, a separate coverlay layer 700 may be laminated in a certain rigid region R1 to protect the exposed outermost outer circuit layer 501.

In the method of manufacturing a flexible printed circuit board in accordance with the present embodiment, after the S500 step, a pad layer 800, which is electrically connected with the outer circuit layers 201, 401, may be formed on the flexible laminates 300, 500 that are laminated in the regions R1, R2, R3 other than the flexible regions F1, F2 (S600, FIG. 7 and FIG. 8).

Here, the S600 step may include the pad layer 800 may include removing a portion of the copper foil layers 330, 530 arranged in outermost surfaces of the flexible laminates 200, 300, 400, 500 and removing portions of the polyimide layers 320, 520 and the adhesive layers 310, 510 by use of laser processing (S610, FIG. 7).

Specifically, a portion of the copper foil layers 330, 530 may be removed through, for example, etching, and the removing of the copper foil layers 330, 530 may be performed simultaneously with the S530 step.

Moreover, when portions of the polyimide layers 320, 520 and the adhesive layers 310, 510 are removed by use of laser processing, the copper foil layers 230, 430 having been laminated therein may function as a laser mask.

Accordingly, portions of the polyimide layers 320, 520 and the adhesive layers 310, 510 may be removed, and the copper foil layers 230, 430 having been laminated therein may be subsequently exposed.

The S600 step may include, after the S610 step, forming the pad layer 800 where the polyimide layers 320, 520 and the adhesive layers 310, 510 are removed (S620, FIG. 8). Here, the pad layer 800 may be formed on the exposed copper foil layers 230, 430 by way of, for example, plating.

Accordingly, the pad layer 800 and the copper foil layers 230, 430 may be electrically connected more readily.

Meanwhile, the pad layer 800 may be formed by laser processing the above-described separate coverlay layer 700 and then exposing the copper foil layer 530 having been laminated therein.

Although a certain embodiment of the present invention has been described above, it shall be appreciated that there can be a variety of permutations and modifications of the present invention by those who are ordinarily skilled in the art to which the present invention pertains without departing from the technical ideas and scope of the present invention, which shall be defined by the appended claims. It shall be also appreciated that a large number of other embodiments than the above-described embodiment are included in the claims of the present invention.

1. A flexible printed circuit board comprising:
a base board comprising a flexible region;
an inner circuit layer formed on the base board;
a flexible laminate laminated on the base board and having a portion thereof removed, the portion having been laminated on the flexible region; and
an outer circuit layer formed on the flexible laminate,
wherein the flexible laminate is formed by having an adhesive layer, a polyimide layer and a copper foil layer sequentially laminated and is arranged and laminated in such a way that the adhesive layer faces the base board.

2. The flexible printed circuit board of claim 1, wherein the flexible region is formed by removing a portion of the flexible laminate, which is laminated on the base board, by use of etching and laser processing, and
wherein the laser processing is performed by using a portion of the copper foil layer of the flexible laminate as a laser mask.

3. The flexible printed circuit board of claim 2, further comprising a coverlay layer laminated on the inner circuit layer formed in the flexible layer,
wherein the coverlay layer is partially or entirely formed by removing the copper foil layer used as the laser mask.

4. The flexible printed circuit board of claim 1,
further comprising a pad layer formed in the flexible laminate laminated in a region other than the flexible region and electrically connected with the outer circuit layer,
wherein the pad layer is partially or entirely formed after removing a portion of the copper foil layer arranged in an outermost surface of the flexible laminate and removing a portion of the polyimide layer and a portion of the adhesive layer through laser processing.

5. A method of manufacturing a flexible printed circuit board, comprising:
providing a base board comprising a flexible region;
forming an inner circuit layer on the base board;
laminating a flexible laminate, which is formed by having an adhesive layer, a polyimide layer and a copper foil layer sequentially laminated, on the base board in such a way that the adhesive layer faces the base board;
forming an outer circuit layer on the flexible laminate; and
removing a portion of the flexible laminate that is laminated in the flexible region.

6. The method of claim 5, wherein the removing of the portion of the flexible laminate that is laminated in the flexible region comprises:
removing a portion of the copper foil layer in the flexible laminate and forming a laser mask constituted with the copper foil layer that is not removed so as to cover the flexible region of the base board; and
removing the polyimide layer and the adhesive layer covering the laser mask through laser processing using the laser mask.

7. The method of claim 6, wherein the removing of the portion of the flexible laminate that is laminated in the flexible region further comprises removing the laser mask, after the removing of the polyimide layer and the adhesive layer covering the laser mask.

8. The method of a claim 5, further comprising forming a pad layer electrically connected with the outer circuit layer in the flexible laminate laminated in a region other than the flexible region, after the removing of the portion of the flexible laminate that is laminated in the flexible region.

9. The method of claim 8, wherein the forming of the pad layer comprises:
removing a portion of the copper foil layer arranged in an outermost surface of the flexible laminate and removing a portion of the polyimide layer and a portion of the adhesive layer through laser processing; and
forming the pad layer where the polyimide layer and the adhesive layer are removed.

10. The flexible printed circuit board of claim 2, further comprising a pad layer formed in the flexible laminate laminated in a region other than the flexible region and electrically connected with the outer circuit layer,
wherein the pad layer is partially or entirely formed after removing a portion of the copper foil layer arranged in an outermost surface of the flexible laminate and removing a portion of the polyimide layer and a portion of the adhesive layer through laser processing.

11. The flexible printed circuit board of claim 3, further comprising a pad layer formed in the flexible laminate laminated in a region other than the flexible region and electrically connected with the outer circuit layer,
wherein the pad layer is partially or entirely formed after removing a portion of the copper foil layer arranged in an outermost surface of the flexible laminate and removing a portion of the polyimide layer and a portion of the adhesive layer through laser processing.

12. The method of claim 6, further comprising forming a pad layer electrically connected with the outer circuit layer in the flexible laminate laminated in a region other than the flexible region, after the removing of the portion of the flexible laminate that is laminated in the flexible region.

13. The method of claim 7, further comprising forming a pad layer electrically connected with the outer circuit layer in the flexible laminate laminated in a region other than the flexible region, after the removing of the portion of the flexible laminate that is laminated in the flexible region.
